(19) United States
(12) Patent Application Publication
(10) Pub. No.: US 2005/0073034 A1
(43) Pub. Date: Apr. 7, 2005

(54) Package for semiconductor chip

(75) Inventor: Takashi Takamura, Chino-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/622,038

(22) Filed: Jul. 17, 2003

Related U.S. Application Data
(62) Division of application No. 09/737,287, filed on Dec. 13, 2000, now abandoned.

(30) Foreign Application Priority Data
Dec. 13, 1999 (JP) 11-353067

(51) Int. Cl. H01L 23/02

(52) U.S. Cl. 257/678

(57) ABSTRACT

The present invention provides a package for enclosing a semiconductor chip and having a plurality of terminals, wherein the terminals are connected with each other by a conductive member in a manner that the electrical connection is disabled by an action of mounting the package on a printed circuit board. During storage, the terminals that are connected by a conductive material are in a short-circuited state until such time immediately before the package is mounted on a printed circuit board. This package prevents high voltage that results from static electricity between the terminals from being applied to circuits of the chip during storage or handling. Therefore, the short-circuited state maintained between the terminals is released after the mounting process, with the result that the operation of the semiconductor chip is not obstructed. The mounting of the package on a printed circuit board may be by soldering the terminals, and the conductive members are solder lines or a conductive thin film that are melt during mounding. The mounting may alternatively be by inserting the terminals into sockets, and the conductive members are wires connecting the terminals that are cut during mounting.

### BACKGROUND OF THE INVENTION

1. Field of the Invention

This invention relates to a package for a semiconductor chip.

2. Description of the Related Art

In conventional art, a semiconductor chip is first installed in a package such as a BGA (Ball Grid Array), and then mounted on a printed circuit board. When the package is stored or handled for the mounting process, a high voltage that results from static electricity may be applied between terminals on the package. As a result, a gate oxide film of a MOSFET may possibly be destroyed. In order to prevent this type of incident, in the conventional technique, an integrated circuit having a MOSFET is provided with an electrostatic protection circuit that is formed from transistors.

### SUMMARY OF THE INVENTION

However, the provision of an electrostatic protection circuit within an integrated circuit is not desirable because it leads to an increased integrated circuit area, and becomes a source of input and output signal delay.

Accordingly, it is an object of the present invention to prevent electrostatic damages within a semiconductor chip in a package when the package is stored or mounted, without providing an electrostatic protection circuit within an integrated circuit.

Additional features and advantages of the invention will be set forth in the descriptions that follow and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the present invention provides a package for enclosing a semiconductor chip comprising a plurality of terminals, and one or more conductive members connecting the terminals to each other in a manner that the electrical connection is disabled by an action of mounting the package on a printed circuit board.

In another aspect, the present invention provides a method for preventing electrostatic damages to a semiconductor chip package during storage, comprising the steps of forming one or more conductive members electrically connecting the terminals to each other, and disabling the electrical connections by an action of mounting the package on a printed circuit board.

By such a package device and method, the terminals that are connected by a conductive material are in a short-circuited state until such time immediately before the package is mounted on a printed circuit board. Therefore, when a high voltage that results from static electricity is applied between the terminals before mounting, the voltage is not applied to circuits of the semiconductor chip that is connected to the terminals. Also, the terminals are connected to one another in a manner that the connection is disabled by an action of mounting the package on a printed circuit board. Therefore, the short-circuited state maintained between the terminals is released after the mounting process, with the result that the operation of the semiconductor chip is not obstructed.

When the action of mounting the package on a printed circuit board is soldering the terminals, solder is used as the conductive material that connects the terminals. By the structure described above, the solder that connects the terminals melts by the heat of the soldering process conducted when mounting the package, and the connections between the terminals are disabled.

When the action of mounting the package on a printed circuit board is inserting the terminals into sockets, a line-like member that is destroyed by the inserting action is used as the conductive material. By this structure, the line-like member is destroyed by the action of inserting the terminals into sockets when the package is mounted, and the connections between the terminals are disabled.

It is to be understood that both the foregoing general description and the following detailed description are exemplary and explanatory and are intended to provide further explanation of the invention as claimed.

### BRIEF DESCRIPTION OF THE DRAWINGS

FIG. 1 is a bottom view of a package in accordance with an embodiment of the present invention.

FIG. 2 is a bottom view of a package in accordance with another embodiment of the present invention, in which a solder thin line pattern is different from the embodiment shown in FIG. 1.

FIG. 3 is a side-view of a package in accordance with another embodiment of the present invention, in which a thin film is formed on the bottom surface of the package.

FIGS. 4(a) and 4(b) illustrate a package in accordance with one embodiment of the present invention, in which the shape of terminals is different from the embodiment shown in FIG. 1.

### DETAILED DESCRIPTION OF THE PREFERRED EMBODIMENTS

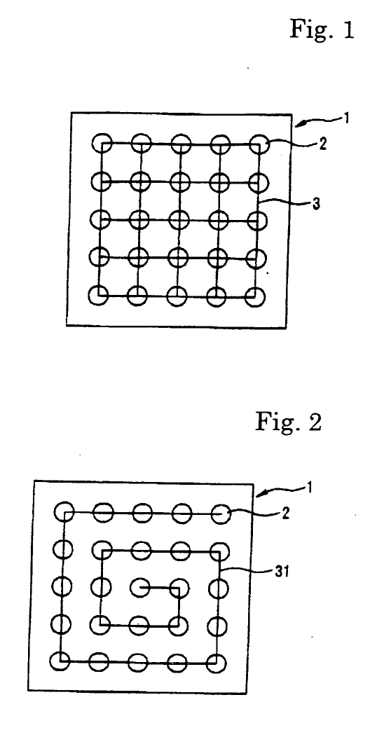

Embodiments of the present invention are described with reference to the drawings. FIG. 1 shows a bottom of a package in accordance with one embodiment of the present invention. The package 1 is a ball grid array (BGA) package. The bottom of the package 1 is provided with a plurality of terminals 2 that are formed of solder balls arranged in a matrix. The package 1 is mounted on a printed circuit board by soldering the solder ball terminals 2. The adjacent terminals 2 are connected in the form of a net by line-like solder members 3 (each having a thickness of 20 μm).

After the solder ball terminals 2 are formed in a matrix on the bottom of the package 1, fine-line solder members 3 are disposed in a matrix over all the columns and rows of the terminals 2, and the fine-line solder members are fixed to the terminals 2 by an ultrasonic pressure bonding or the like, while the bottom of the package 1 faces up.

By the package 1 described above, all of the terminals 2 are connected by the solder 3 until such time immediately before mounting the package on a printed circuit board, and therefore all of the terminals 2 are in a short-circuited state. As a result, when a high voltage that results from static electricity is applied between any ones of the terminals 2 on the package 1, the voltage is not applied to the circuit of the semiconductor chip, and therefore, the electrostatic breakdown of elements within the semiconductor chip can be prevented.

Also, when the terminals 2 are soldered to a printed circuit board for mounting the package, the line-like solder members 3 that connect the adjacent terminals 2 are melted by the heat, and all of the terminals 2 are separated. Therefore, after mounting the package 1, the short-circuited state of all of the terminals on the package 1 is removed, and the operation of the semiconductor chip is not obstructed.

For connecting the terminals by a line-like solder members, it is not necessary to form the solder members in the form of a net as shown in the embodiment described above. For example, all adjacent ones of the terminals may be connected to one another by a single line-like solder member 31, as shown in FIG. 2. Also, instead of the solder member, an electrically conductive paint that includes particles of an alloy of tin-indium (that is one composition of solder) may be used, and the terminals 2 may be connected to one another by a thin-line pattern of the paint.

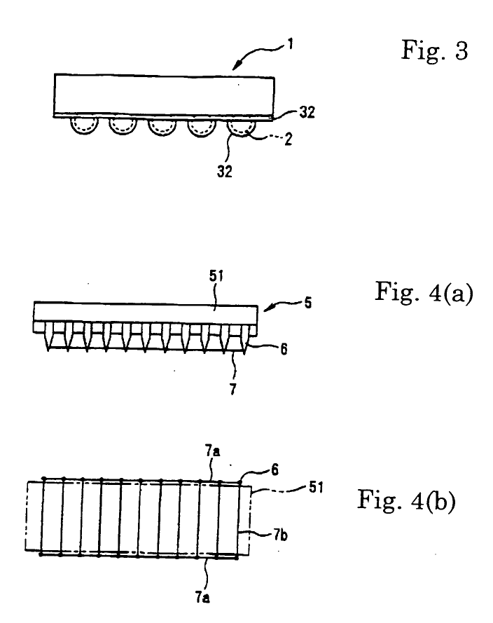

Also, as shown in FIG. 3, a thin film 32 composed of an alloy of tin-indium (that is one composition of solder) may be formed on the bottom surface of the package 1, to thereby connect all of the terminals 2 on the package 1.

In this case, the thin film 32 is formed on the bottom face of the package 1 where the solder ball terminals 2 are formed in a matrix to a thickness of about 2 μm by, for example, a sputtering method, using a tin-indium alloy as a target. By this, the solder thin film 32 is formed on the surfaces of the solder balls 2, areas between the terminals 2 and peripheral areas of the bottom surface of the package 1. As a result, all of the terminals 2 on the package 1 are connected to one another by the conductive material.

When the terminals 2 are soldered to a printed circuit board upon mounting the package, the solder 3 forming the thin film 32 between the terminals 2 is fused by the heat, and all of the terminals 2 are separated from one another. In other words, when the solder between the terminals 2 melts, the thin film 32 that is composed of solder also melts. Since the areas between the terminals 2 and the peripheral areas of the bottom surface of the package 1 are not treated for increasing wettability, the solder that exists in these areas as the thin film 32 moves by its surface tension and forms itself into ball-shaped objects after it is melted. As a result, the connection between all of the terminals 2 by the thin film is eliminated. Therefore, after mounting the package 1, the short-circuited state of all of the terminals 2 on the package 1 is eliminated, and the operation of the semiconductor chip is not affected after the package is mounted.

The solder forming the thin film 32 may move after it melts and may solidify between the terminals 2 to thereby form new connections between the terminals 2 after mounting the package. In order to prevent this from occurring, the thin film 32 may preferably be pre-patterned by a photolithography process and an etching process to thereby remove excess portions of the thin film 32 from unnecessary areas. In this case, when the thin film 32 is patterned, a logo mark of a manufacturer may also be patterned. As a result, the process for printing the logo mark can be eliminated, and therefore the number of steps required for patterning the thin film 32 may be reduced.

FIGS. 4(a) and 4(b) show a package 5 in accordance with another embodiment of the present invention. FIG. 4(a) is a side elevation of the package, and FIG. 4(b) is a bottom view of the package.

The package 5 is a dual inline package (DIP). Many pin-shaped terminals 6 are formed on both lower sides of a main body 51. The package 5 is mounted on a printed circuit board by inserting the terminals 6 in sockets. All of the terminals 6 on the package 5 are connected at their tip portions by a thin gold wire 7 (having a thickness of 70 μm). As shown in FIG. 4(b), the terminals 6 provided on each side of the main body 51 are connected by a gold wire 7a, respectively, and each opposing ones of the terminals 6 provided along the two sides are connected by gold wires 7b. The gold wires 7 may be fixed to the terminals 6 by an ultrasonic pressure bonding method or the like.

By the package 5 described above, all of the terminals 6 are connected by the gold wires 7 until such time immediately before mounting the package on a printed circuit board, such that all of the terminals are in a short-circuited state. Therefore, when a high voltage that results from static electricity is applied between any ones of the terminals 2 on the package 1, the voltage is not applied to the circuit of the semiconductor chip, and therefore, the electrostatic destruction of elements within the semiconductor chip can be prevented.

When the terminals 6 are inserted in the sockets upon mounting the package, all of the gold wires 7 are cut, and thus all of the terminals 6 are separated from one another. Therefore, the short-circuited state of all of the terminals 6 on the package 5 is eliminated, with the result that the operation of the semiconductor chip is not obstructed by the wires after mounting the package.

For example, the package 5 may be applied to post-mountable semiconductor apparatuses such as expansion memories for personal computers. Conventionally, in this type of semiconductor apparatuses, the package is wrapped by a conductive plastic, or an electrostatic prevention tool such as a wrist strap is used to prevent electrostatic destruction when the package is mounted. However, by using the package 5 of the present embodiment as a package for a post-mountable semiconductor apparatus, the package does not need to be wrapped by a conductive plastic, or an electrostatic prevention tool such as a wrist strap is not needed when the package is mounted.

In each of the embodiments described above, all of the terminals are connected by a conductive member to thereby place all of the terminals in a short-circuited state until such time immediately before mounting the package on a printed circuit board. Therefore, when a high voltage that results from static electricity is applied between any ones of the terminals on the package, the voltage is not applied to the circuit of the semiconductor chip, and therefore, the electrostatic destruction of elements within the semiconductor chip can be prevented. However, the package of the present invention is not limited to the embodiments described above. The package of the present invention includes those in which at least two terminals are connected to each other by a conductive member. However, since the same effects as described above are not obtained for terminals that are not connected by conductive members, conductive members may preferably connect all of the terminals that are connected to semiconductor devices.

It is noted that the present invention may not necessarily be applied only when an electrostatic protection circuit is not provided within an integrated circuit. In other words, the present invention may be applied when an electrostatic protection circuit is provided within an integrated circuit. In other words, when a package may contain a semiconductor chip of an integrated circuit having an electrostatic protection circuit, terminals on the package may be connected by conductive members in a manner that the electrical connections are disabled by an action of mounting the package on a printed circuit board. As a result, a greater electrostatic protection effect is obtained.

Thus, by a package in accordance with the present invention, electrostatic destruction of a semiconductor chip within the package can be prevented when the package is stored or mounted, without requiring an electrostatic protection circuit within an integrated circuit, and without obstructing the operation of the semiconductor chip after the package is mounted.

It will be apparent to those skilled in the art that various modifications and variations can be made in a package device and method of the present invention without departing from the spirit or scope of the inventions. Thus, it is intended that the present invention cover modifications and variations of this invention that come within the scope of the appended claims and their equivalents.

1-5. (Canceled)

6. A method for preventing electrostatic damages to a semiconductor chip package during storage, the package having a plurality of terminals, the method comprising:
forming one or more conductive members electrically connecting the terminals to each other, thereby short-circuiting the terminals so that voltage is not applied to the semiconductor chip package; and
disabling the electrical connections by an action of mounting the package on a printed circuit board, wherein the electrical connections are melted by a heat of soldering the terminals so that operation of the semiconductor chip package is not obstructed.

7. The method of claim 6, wherein the step of forming the conductive members comprises forming solder members connecting the terminals, and wherein the action of mounting the package comprises soldering the terminals.

8. The method of claim 7, wherein the step of forming the conductive members comprises forming solder lines connecting the terminals.

9. The method of claim 7, wherein the step of forming the conductive members comprises forming a conductive thin film.

10. The method of claim 6, wherein the terminals are pin-shaped having protruding tips, and the step of forming the conductive members comprises forming conductive wires connected at the tips of the terminals, and wherein the action of mounting the package comprises inserting the terminals into sockets.

11. (Canceled)

12. The method of claim 9, wherein the step of forming the conductive thin film comprises patterning the conductive thin film by a photolithography process and an etching process.

13. The method of claim 8, wherein the solder lines are formed to a net-like structure.

14. The method of claim 8, wherein the solder lines are formed to a single line-like solder member.

15. The method of claim 9, wherein the step of forming the conductive thin film comprises forming the conductive thin film on the terminals.
